(19) United States
(12) Patent Application Publication
(10) Pub. No.: US 2011/0235285 A1
(43) Pub. Date: Sep. 29, 2011

(54) INTERFACE PORT CONFIGURATION TO REDUCE CONNECTION INTERFERENCE

(76) Inventors: Thomas Cloonan, Lisle, IL (US); Gregory J. Cyr, Winfield, IL (US)

(21) Appl. No.: 13/069,481

(22) Filed: Mar. 23, 2011

Related U.S. Application Data
(60) Provisional application No. 61/316,554, filed on Mar. 23, 2010.

(51) Int. Cl. H05K 7/00

(52) U.S. Cl. 361/748; 361/679.01

(57) ABSTRACT

Methods and apparatuses for reducing connection interference within and across adjacent interfaces are provided. An interface includes ports arranged along at least a first axis and second axis. The ports on the first axis are offset from the ports on the second axis. When two interfaces are provided adjacent to each other, the ports on the last axis of the first circuit board are offset from the ports on the first axis of the second circuit board.

### CROSS REFERENCE TO RELATED APPLICATION

This application claims the benefit of U.S. Provisional Application Ser. No. 61/316,554 (“the '554 Application”), which was filed on Mar. 23, 2010, and entitled “A Connector Arrangement for High-Density Input/Output Connectivity into a Network Node.” The '554 Application is incorporated herein by reference in its entirety.

### TECHNICAL FIELD

This disclosure is related to port configurations for network equipment.

### BACKGROUND

A Data-Over-Cable Service Interface Specification (DOCSIS) system, for example, can be used to deliver high-definition digital entertainment and telecommunications such as video, voice, and high-speed Internet to subscribers over an existing cable television network. The cable television network can take the form of an all-coax, all-fiber, or hybrid fiber/coax (HFC) network. A cable service provider, such as a multiple service operator (MSO), can deliver these services to subscribers by using a cable modem termination system (CMTS) located at a headend and cable modems (CMs) and customer premise equipment (CPE) devices, such as set-top boxes, multimedia terminal adapters (MTAs), and gateway devices, located at subscriber premises.

As more traffic is transmitted between the CMTS and CMs due to, for example, an increase in the data rates demanded by CMs served by the network and/or delivery of expanded services such as video-on-demand, there is a need to increase the number of input and output ports in the CMTS to deliver and receive such traffic. A CMTS can include one or more interface cards that serve as RF interfaces between the headend and CMs. Each interface card can have multiple ports for upstream and downstream traffic. As traffic increases between the CMTS and CMs, the service provider can increase the number of ports in the CMTS by adding new line cards and/or by increasing the number of ports in one or more interface cards. Due to space constraints, for example, increasing the number of interface cards may not be a desirable option. Accordingly, equipment vendors are supplying interface cards with more ports.

### BRIEF DESCRIPTION OF THE DRAWINGS

FIG. 1 is a block diagram illustrating an example DOCSIS-based system used to provide communications between a CMTS and a CM over a network.

FIG. 2 is a block diagram illustrating an example RF interface portion of the back-side of a CMTS which includes one or more interface cards.

FIG. 3 illustrates an example port arrangement for an interface card.

FIG. 4A illustrates the port offset between interface cards achieved by using interface cards having two different port configurations.

FIG. 4B illustrates the port offset between the interface cards achieved by using the same port configuration but staggering the interface cards.

FIG. 5 illustrates an example two axis port configuration.

FIG. 6A illustrates the space between ports across interface cards having the port configuration of FIG. 3.

FIG. 6B illustrates the space between ports across interface cards having the two axis port configuration of FIG. 5.

### DETAILED DESCRIPTION

Various implementations of this disclosure can operate to reduce connection interference within and across adjacent interfaces having ports arranged on a plurality of axes by offsetting the ports on one axis from the ports on an adjacent axis.

Although this disclosure makes reference to a DOCSIS-based system and CMTSs, this disclosure is not intended to be limited to a DOCSIS-based system or CMTS. This disclosure can be applied to other communication systems including wired or wireless systems. This disclosure also can be applied to any network node or network equipment including routers, switches, servers, DSL equipment, passive optical network (PON) equipment such as optical line terminals (OLT), etc., or any other equipment, including stand-alone equipment.

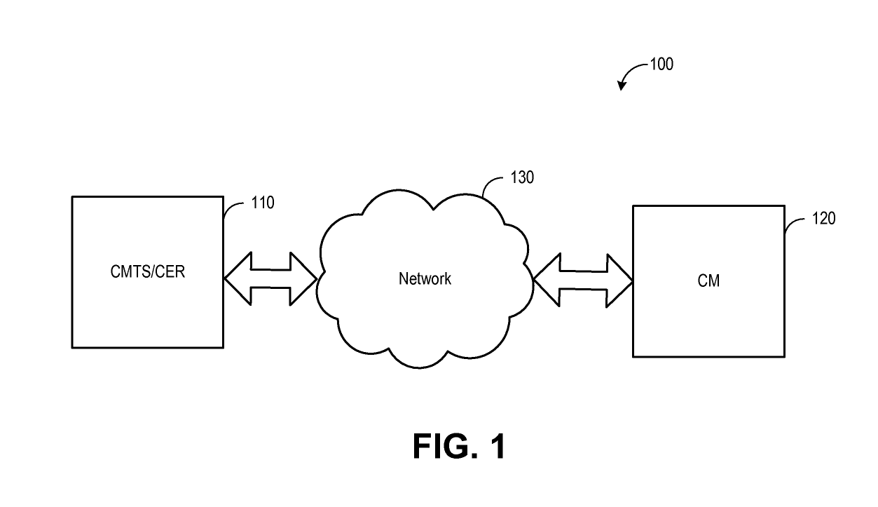

FIG. 1 illustrates an example DOCSIS-based system operable to deliver high-definition digital entertainment and telecommunications such as video, voice, and high-speed Internet to a subscriber over an existing cable television network. As shown in FIG. 1, traffic (e.g., data, video, and voice signal) can be transferred over a cable network 130 between a CMTS 110 or converged edge router (CER) and a CM 120. The cable network 130 can take the form of an all-coax, all-fiber, or hybrid fiber/coax (HFC) network.

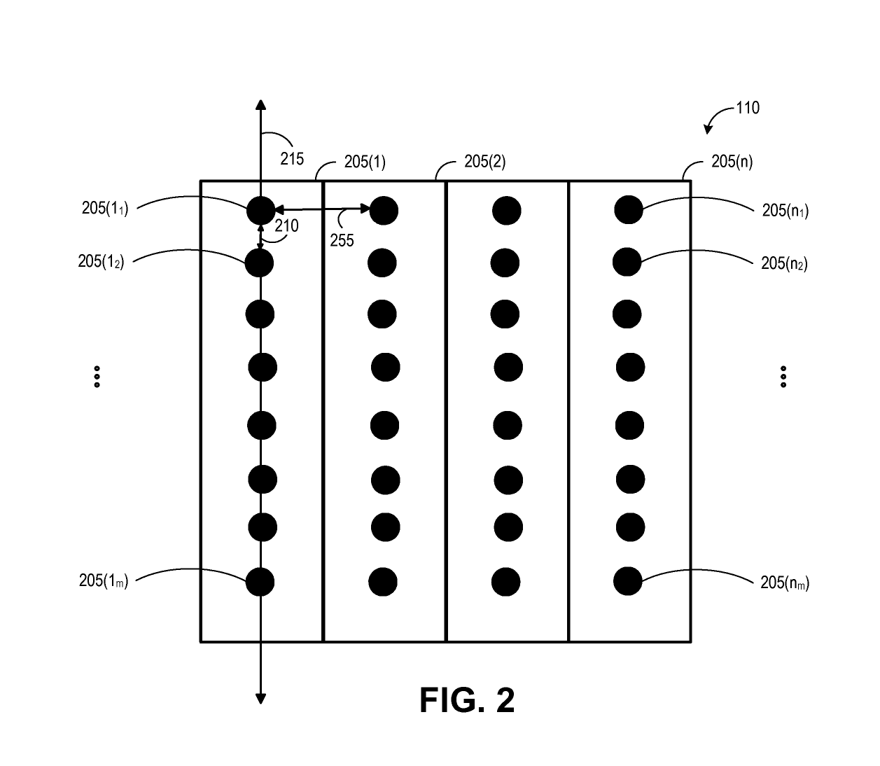

FIG. 2 illustrates an example RF interface portion of the back-side of a CMTS 110. The RF interface portion of the CMTS 110 can include one or more interface cards 205(1), 205(2), . . . 205(n) that serve as RF interfaces between the headend and CMs. Each interface card 205(i), i=1, . . . n, can have a plurality of ports 205(iⱼ), j=1, . . . m, arranged on a panel or face plate for upstream and downstream traffic. As discussed above, as traffic increases between the CMTS/CER 110 and CMs, the service provider can increase the number of ports in the CMTS 110 by adding new interface cards and/or by increasing the number of ports of one or more interface cards. As discussed above, increasing the number of interface cards may not be a desirable option, therefore, equipment vendors are supplying interface cards with more ports.

Interface cards with an increased number of ports can be achieved by reducing the space 210 between ports to fit more ports on the interface card. The ports can be arranged on a single axis 215 (e.g. a horizontal or vertical axis, depending on the orientation of the interface card) as shown in FIG. 2.

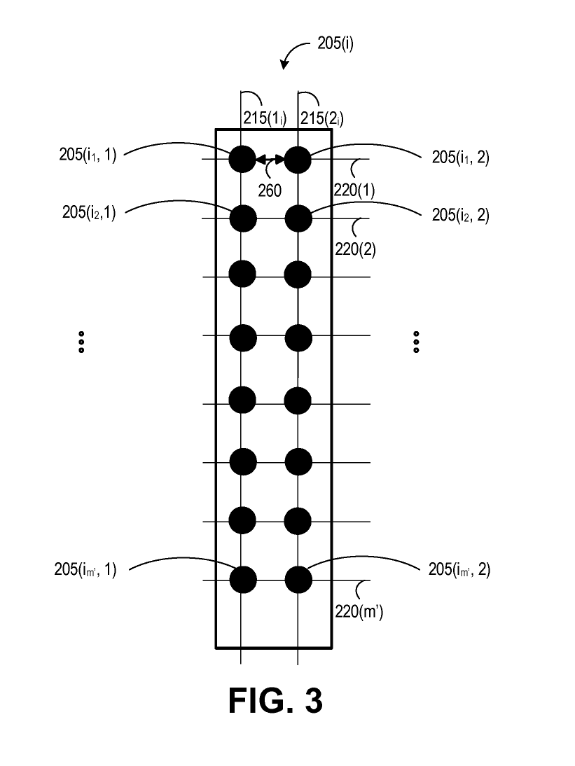

Alternatively, as shown in FIG. 3, the ports on an interface card, for example the i-th interface card 205(i) of FIG. 2, can be arranged on two parallel axes 215(1ᵢ), 215(2ᵢ). For this disclosure, 205(iⱼ, k) represents the j-th port on the k-th axis of the i-th interface card. Each port 205(iⱼ, 1), j=1, . . . m′ on the first axis of the i-th interface card 215(1ᵢ) is aligned with the corresponding port 205(iⱼ, 2), j=1, . . . m′, respectively, on the second axis 215(2ᵢ). That is, for each port 205(iⱼ, 1), j=1, . . . m′ on the first axis 215(1ᵢ) and the corresponding port 205(iⱼ, 2), j=1, . . . m′, respectively, on the second axis 215(2ᵢ), an axis 220(j), j=1, . . . m′, that is perpendicular to the first and second axes 215(1ᵢ), 215(2ᵢ) and passing through the port can be drawn.

As equipment vendors attempt to increase the number of ports on an interface card, the space between the ports can become too small to easily insert, connect, disconnect, or remove a connector. Furthermore, as connections (e.g., connectors and/or cables) are attached to the ports on the interface card, it can become increasingly difficult to insert, connect, disconnect, or remove connectors due to the added interference from the connections. This interference can be referred to as intra-card connection interference.

Inter-card connection interference can also occur. That is, referring to FIG. 2, the ports on one interface card (e.g., interface card 205(1)) and/or the connections to the ports on the interface card can interfere with inserting, connecting, disconnecting, or removing connectors to ports on an adjacent interface card (e.g., interface card 205(2)).

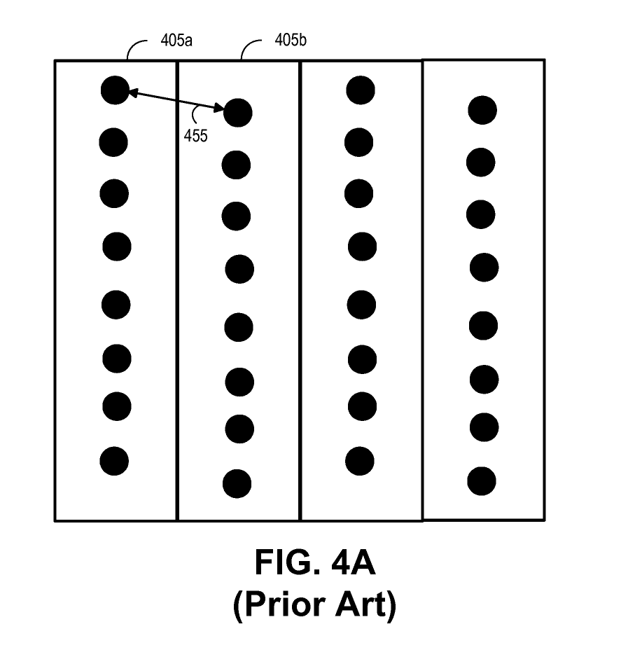

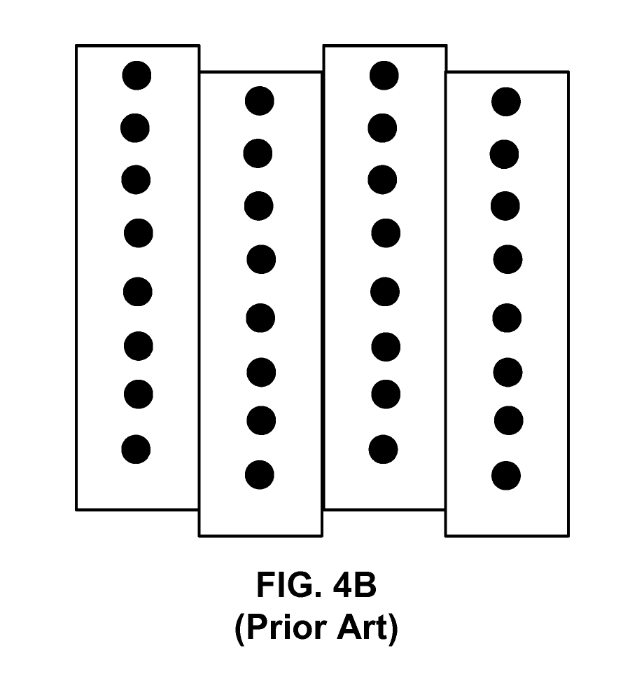

For interface cards having ports arranged on a single axis, U.S. Pat. No. 6,457,978, , entitled “Method And Apparatus For Arranging Cable Connectors To Allow For Easier Cable Installation,” which was issued on Oct. 1, 2002, and is incorporated herein by reference in its entirety, addresses inter-card connection interference. Referring to FIG. 4A, the '978 Patent discloses using two different interface cards 405a, 405b where the ports on the first interface card 405a are offset from the ports on the second interface card 405b. When the two interface cards 405a, 405b are inserted adjacent to one another, the ports on the first interface card are staggered/offset from the ports on the second interface card thereby increasing the space 255 (see FIG. 2) between ports across interface cards. Thus, the space 455 between ports across the interface cards 405a, 405b can be greater than the space 255 between ports across the interface card 205(1), 205(2). Referring to FIG. 4B, the '978 Patent discloses in an alternate embodiment using identical interface cards, instead of using two different interface cards, to achieve port offset between the interface cards by staggering the interface cards.

However, the '978 patent does not address intra-card connection interference. Further, the '978 patent does not address intra- and inter-card connection interference for interface cards having ports arranged on a plurality of axes.

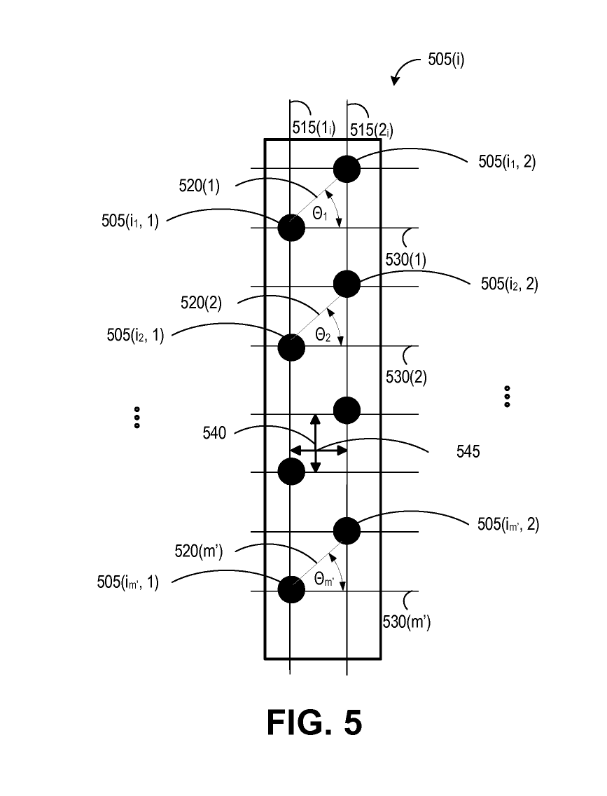

FIG. 5 illustrates an example two axis port configuration that can reduce intra- and inter-card connection interference. For the purpose of illustration, assume the total number of ports on each interface card of FIGS. 2, 3, and FIG. 5 equals 8 (i.e., m=8 and m′=4). As shown in FIG. 5, the ports on an i-th interface card 505(i) can be arranged on two parallel axes 515(1ᵢ), 515(2ᵢ). The ports 505(iⱼ, 1), j=1, . . . m′ on the first axis 515(1ᵢ) are staggered/offset from the ports 505(iⱼ, 2), j=1, . . . m′ on the second axis 515(2ᵢ) to provide more free space around the ports thereby reducing intra-card connection interference. That is, for each port 505(iⱼ, 1), j =1, . . . m′ on the first axis 515(1ᵢ) and the corresponding port 505(iⱼ, 2), j=1, . . . m′, respectively, on the second axis 515(2ᵢ), if an axis 520(j), j=1, . . . m′, respectively, was drawn that passes through the ports, the axis would be rotated a certain number of degrees, θⱼ, j=1, . . . m′, respectively, from an axis 530(j) j=1, . . . m′, respectively, extending perpendicular from the first or second axis 515(1ᵢ), 515(2ᵢ). Thus, with this configuration, the amount of free space around the ports of the interface card of FIG. 5 can be greater than the amount of free space around the ports of the interface cards of FIG. 2 and FIG. 3.

Although FIG. 5 illustrates four ports for each axis (i.e., m′=4), more are less ports can be included on each axis by, for example, decreasing or increasing the vertical distance 540 between ports. Assuming the orientation of the interface card as shown in FIG. 5, in some implementations, the vertical distance (e.g., vertical distance 540) between each port and the horizontal distance (e.g., horizontal distance 545) can be equal. In some implementations the vertical distance between each port is greater than the horizontal distance between each port. In some implementations, the vertical distance between each port is less than the horizontal distance between each port. In some implementations, θⱼ=θ, j=1, . . . m′. In some implementation θⱼ, j=1, . . . m′ can vary. In some implementations, only a portion of an interface card is configured in the two axis port configuration illustrated in FIG. 5.

In some implementations, there can be varying vertical distances between ports in a single interface card.

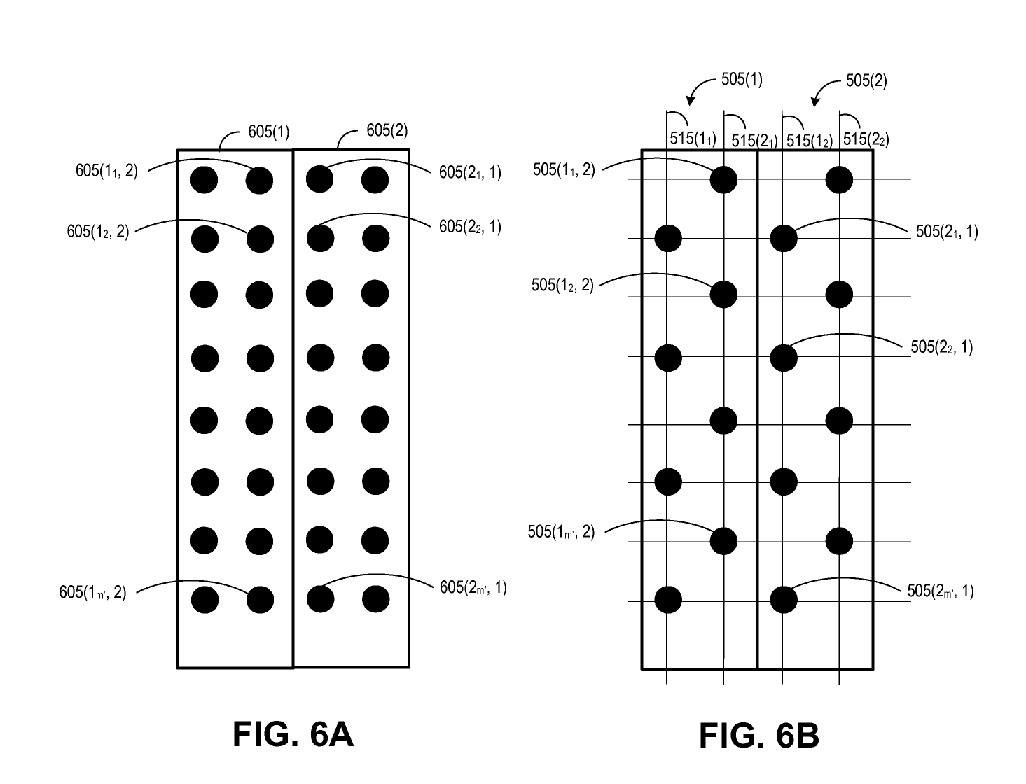

FIG. 6B illustrates how the two axis port configuration of FIG. 5 can increase the amount of free space around the ports across interface cards thereby reducing inter-card connection interference. For the purpose of illustration, assume the total number of ports on each interface card of FIGS. 2, 6A, 6B equals 16 (i.e., m=16, m′=8). When a first interface card 505(1) is placed adjacent to a second interface card 505(2), the ports 505(2ⱼ, 1), j=1, . . . m′ on the first axis 515(1₂) of the second interface card 505(2) will be staggered/offset from the ports 505(1ⱼ, 2), j=1, . . . m′, respectively, on the second axis 515(2₁) of the first interface card 505(1). Thus, the amount of free space around the ports 505(1ⱼ, 2) and 505(2ⱼ, 1), j=1, . . . m′ can be greater than the amount of free space around the ports 605(1ⱼ, 2) and 605(2ⱼ, 1), j=1, . . . m′ of FIG. 6A and can be greater than the amount of free space around the ports across the interface cards of FIG. 2.

The two axis port configuration of FIG. 5 offers one or more advantages over the prior art arrangements. First, only a single port configuration is needed to reduce inter-card connection interference. Second, the interface cards do not need to be staggered to achieve port offset between interface cards.

In some implementations, the ports on the interface cards can be arranged in a staggered fashion on three or more parallel axes.

While this specification contains many specific implementation details, these should not be construed as limitations on the scope of any invention or of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

1. An interface for reducing connection interference, comprising:
a first set of one or more ports arranged along a first axis wherein the first axis extends along the interface in a lengthwise direction; and
a second set of one or more ports arranged along a second axis wherein the second axis extends along the interface in the lengthwise direction and is parallel to the first axis;
wherein the first set of ports on the first axis are offset in the lengthwise direction from the second set of ports on the second axis.

2. The interface of claim 1 wherein the first set of ports on the first axis and the second set of ports on the second axis are arranged along a portion of the interface in a lengthwise direction.

3. The interface of claim 1 wherein the interface is an interface of an interface card for a CMTS.

4. A method for reducing connection interference, the method comprising:
providing a first interface including one or more ports arranged along each of a plurality of parallel axes extending along the first interface in a lengthwise direction; and
providing a second interface adjacent to the first interface wherein the second interface includes one or more ports arranged along each of a plurality of parallel axes extending along the second interface in a lengthwise direction;
wherein the ports on the last axis of the first interface are offset in the lengthwise direction from the ports on the first axis of the second interface.

5. The method of claim 4 wherein the port configuration of the first interface is identical to the port configuration of the second interface.

6. The method of claim 4 wherein the port configuration of the first interface is different than the port configuration of the second interface.

7. The method of claim 4 wherein the ports of the first interface are configured for a first type of connector and the ports of the second interface are configured for a second type of connector.

8. The method of claim 4 wherein one or more of the set of ports arranged along an axis is arranged along a portion of an interface in a lengthwise direction.

9. The method of claim 4 wherein the first and second interfaces are interfaces of interface cards for a CMTS.
